(19) United States
(12) Patent Application Publication
(10) Pub. No.: US 2008/0128020 A1
(43) Pub. Date: Jun. 5, 2008

(54) Photovoltaic devices including a metal stack

(75) Inventors: Syed Zafar, Perrysburg, OH (US); Greg Helyer, Toledo, OH (US); Nelson Christopher DeVoe, Perrysburg, OH (US)

Correspondence Address: STEPTOE & JOHNSON LLP, 1330 CONNECTICUT AVENUE, N.W., WASHINGTON, DC, 20036, US

(73) Assignee: First Solar, Inc., Perrysburg, OH (US)

(21) Appl. No.: 11/939,878

(22) Filed: Nov. 14, 2007

Related U.S. Application Data
(60) Provisional application No. 60/868,023, filed on Nov. 30, 2006.

(51) Int. Cl. H01L 31/04; B05D 1/00

(52) U.S. Cl. 136/252; 427/74

(57) ABSTRACT

A photovoltaic device can include metal layer in contact with a semiconductor layer.

### CLAIM FOR PRIORITY

This application claims priority under 35 U.S.C. § 119(e) to U.S. Patent Application Ser. No. 60/868,023 filed on Nov. 30, 2006, which is hereby incorporated by reference.

### TECHNICAL FIELD

This invention relates to photovoltaic devices.

### BACKGROUND

During the fabrication of photovoltaic devices, layers of semiconductor material can be applied to a substrate. A thin metal layer is typically deposited as an electrical contact to a semiconductor layer for photovoltaic device operation. In order to enhance performance of the photovoltaic device, it can be desirable to use a metal layer that has adequate metal adhesion for reliable operation of commercial modules.

### SUMMARY

In general, a photovoltaic device includes a transparent conductive layer, a semiconductor layer, a substrate supporting the semiconductor layer, and a metal layer in contact with a semiconductor layer. The metal layer can contain a metal with a thermal expansion coefficient greater than the thermal expansion coefficient of a semiconductor layer. The metal layer can be a nickel-containing layer. The photovoltaic device can further include a second metal layer deposited over the first metal layer. The first metal layer can have a thermal expansion coefficient greater than the thermal expansion coefficient of the semiconductor layer, but less than the thermal expansion coefficient of the second metal layer.

In another aspect, a photovoltaic device can include a composite metal layer including a first metal layer in contact with a semiconductor layer, a second metal layer including tungsten, molybdenum, iridium, tantalum, titanium, neodymium, palladium, lead, iron, silver, or nickel, the second layer in contact with the first metal layer, and a third metal layer in contact with the second layer. The second layer can have a thickness of greater than 100 Å, greater than 500 Å, greater than 1000 Å, or greater than 2000 Å. The second layer can have a thermal expansion coefficient greater than the first layer and less than the third layer.

A system for generating electrical energy can include a transparent conductive layer, a semiconductor layer, a substrate supporting the semiconductor layer, and a first metal layer in contact with a semiconductor layer, a second metal layer including tungsten, molybdenum, iridium, tantalum, titanium, neodymium, palladium, lead, iron, silver, or nickel, the second layer in contact with the first metal layer, and a third metal layer in contact with the second layer.

A method of making a photovoltaic device substrate can include placing a semiconductor layer on a substrate, depositing a first metal layer in contact with a semiconductor layer, depositing a second metal layer including tungsten, molybdenum, iridium, tantalum, titanium, neodymium, palladium, lead, iron, silver, or nickel, the second layer in contact with the first metal layer, and depositing a third metal layer.

In certain circumstances, a first metal layer can be a chromium-containing layer, and a third metal layer can be an aluminum-containing layer. In another embodiment, a photovoltaic device can further comprise a fourth layer, wherein the fourth layer is an intermediate layer between the second metal layer and the third metal layer. The intermediate layer can be a nickel-containing layer. The intermediate layer can have a thickness of greater than 100 Å, greater than 500 Å, greater than 1000 Å, or greater than 2000 Å. The intermediate layer can have a thermal expansion coefficient greater than the second layer and less than the third layer.

In another embodiment, a second semiconductor layer can be deposited over a semiconductor layer. The semiconductor layer can include CdS or CdTe. The second semiconductor layer can include CdTe.

In yet another embodiment, a photovoltaic device can further comprise a fifth metal layer between the fourth metal layer and the third metal layer. The fifth layer can include lead, palladium, nickel, or silver. The fifth layer can have a thickness of greater than 100 Å, greater than 500 Å, greater than 1000 Å, or greater than 2000 Å. The intermediate layer can have a thermal expansion coefficient greater than the fourth layer and less than the third layer.

The details of one or more embodiments are set forth in the accompanying drawings and the description below. Other features, objects, and advantages will be apparent from the description and drawings, and from the claims.

### DESCRIPTION OF DRAWINGS

FIG. 1 is a schematic of a substrate with multiple layers.

FIG. 2 is a schematic of a substrate with multiple layers.

FIG. 3 is a schematic of a substrate with multiple layers.

### DETAILED DESCRIPTION

A photovoltaic device can be constructed of a series of layers of semiconductor materials deposited on a glass substrate. In an example of a common photovoltaic device, the multiple layers can include: a bottom layer that is a transparent conductive layer, a window layer, an absorber layer, and a top layer. The top layer can be a metal layer. Each layer can be deposited at a different deposition station of a manufacturing line with a separate deposition gas supply and a vacuum-sealed deposition chamber at each station as required. The substrate can be transferred from deposition station to deposition station via a rolling conveyor until all of the desired layers are deposited. Additional layers can be added using other techniques such as sputtering. Electrical conductors can be connected to the top and the bottom layers respectively to collect the electrical energy produced when solar energy is incident onto the absorber layer. A top substrate layer can be placed on top of the top layer to form a sandwich and complete the photovoltaic device.

The bottom layer can be a transparent conductive layer, and can be for example a transparent conductive oxide such as zinc oxide, zinc oxide doped with aluminum, tin oxide or tin oxide doped with fluorine. Sputtered aluminum doped zinc oxide has good electrical and optical properties, but at temperatures greater than 500° C., aluminum doped zinc oxide can exhibit chemical instability. In addition, at processing temperatures greater than 500° C., oxygen and other reactive elements can diffuse into the transparent conductive oxide, disrupting its electrical properties.

The window layer and the absorbing layer can include, for example, a binary semiconductor such as group II-VI, III-V or IV semiconductor, such as, for example, ZnO, ZnS, ZnSe, ZnTe, CdO, CdS, CdSe, CdTe, MgO, MgS, MgSe, MgTe, HgO, HgS, HgSe, HgTe, AlN, AlP, AlAs, AlSb, GaN, GaP, GaAs, GaSb, InN, InP, InAs, InSb, TlN, TlP, TlAs, TlSb, or mixtures thereof. An example of a window layer and absorbing layer is a layer of CdS coated by a layer of CdTe.

A top layer can cover the semiconductor layers. The top layer can include a metal such as, for example, chromium, nickel or aluminum. A top layer can be metal layer. A metal layer can be deposited as an electrical contact to a semiconductor layer for solar device operation. A metal layer can be a composite layer comprised of metal layers, such as a Cr/Al/Cr metal stack. The metal layers in a composite layer can be metals that have a thermal expansion coefficient between the semiconductor layer and a first metal layer. Metal adhesion is impacted by intrinsic stress, which is a function of deposition variables. Metal adhesion is also impacted by extrinsic stresses such as post-deposition thermal treatment in which case dissimilarity in thermal expansion coefficients may contribute to reduced adhesion. A proper sequential arrangement of metals, such as chromium, nickel, and aluminum, can provide a gradient in thermal expansion of the metal stack thereby minimizing loss of adhesion during thermal processing.

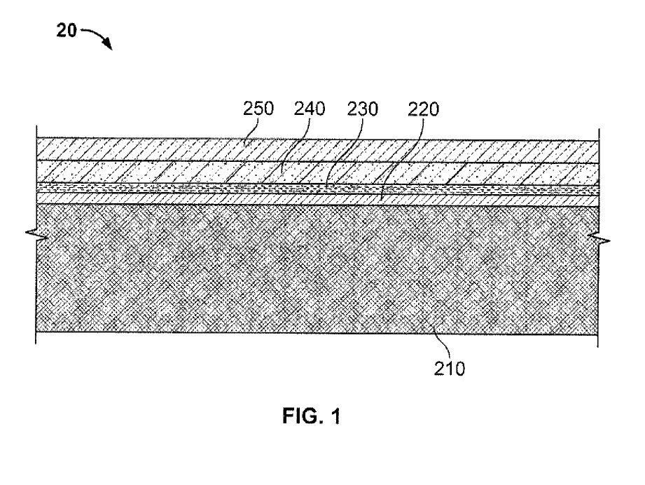

Referring to FIG. 1, a photovoltaic device 20 can include composite metal layer comprising a plurality of metal layers, such first metal layer 240 and a second metal layer 250. The second metal layer can be deposited over a first metal layer or between the first metal layer and a third metal layer. For example, the first metal layer can be a chromium-containing layer; the second metal layer can be a nickel-containing layer; and the third metal layer can be an aluminum-containing layer. The third metal layer can have a thickness of greater than 100 Å, greater than 500 Å, greater than 1000 Å, or greater than 2000 Å. The nickel-containing layer can be positioned between the chromium-containing layer and an aluminum-containing layer (Cr/Ni/Al). The second metal layer can have a thermal expansion coefficient greater than the first metal layer and less than the third metal layer. The first metal layer can be in contact with a semiconductor layer 230. A transparent conductive layer 220 can be deposited over the substrate 210.

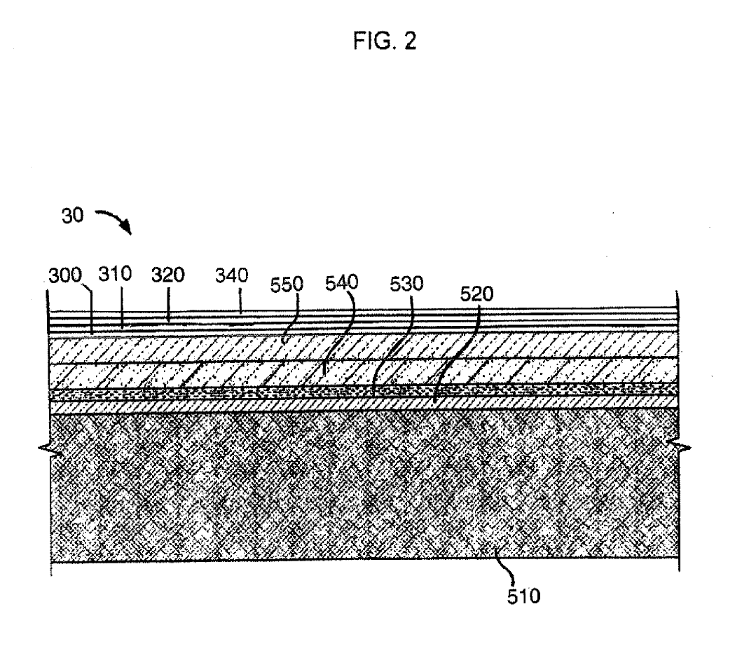

Referring to FIG. 2, a photovoltaic device 30 can include a composite metal layer comprising a first metal layer 300, a second metal layer 310, a third metal layer 320, and a fourth metal layer 340. The fourth metal layer can be an intermediate layer. An intermediate layer can be positioned between any of the first, second, or third layers. The intermediate layer can have a thickness of greater than 100 Å, greater than 500 Å, greater than 1000 Å, or greater than 2000 Å. The intermediate layer can have a thermal expansion coefficient greater than the second metal layer and less than the third metal layer. Additional metal layers, such as a fifth metal layer, and so forth, can also be added. Additional metal layers can have different or similar thermal expansion coefficients. The photovoltaic device can include a substrate 510, upon which are deposited various layers of the photovoltaic device. The first layer deposited on the substrate can be a transparent conductive layer 520. A first semiconductor layer 540 can be deposited over the transparent conductive layer. A capping layer or a protective layer 530 can be deposited between a semiconductor layer and the transparent conductive layer. A second semiconductor layer 550 can be deposited over the first semiconductor layer. The first metal layer can be in contact with a second semiconductor layer.

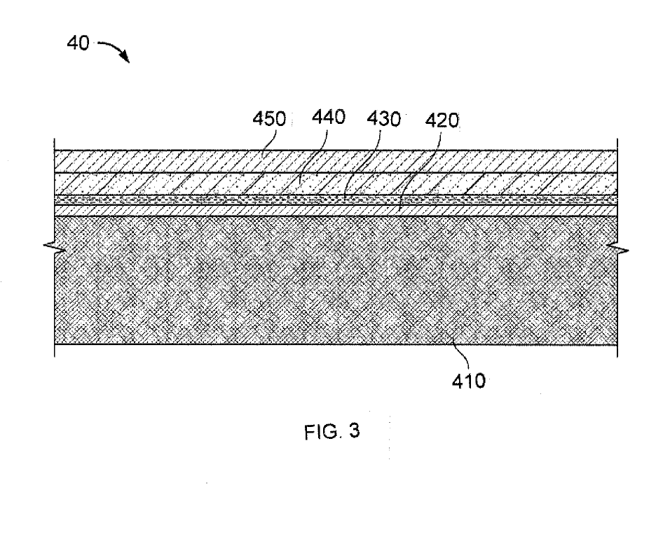

Referring to FIG. 3, a photovoltaic device 40 can include a metal layer 450. The metal layer can be a nickel-containing layer. The metal layer can be deposited over a semiconductor layer 440. A capping layer or a protective layer 430 can be deposited between a semiconductor layer and a transparent conductive layer 420. The transparent conductive layer 420 can be a first layer deposited on a substrate 410.

The first layer can have a thickness of greater than 100 Å, greater than 500 Å, greater than 1000 Å, or greater than 2000 Å. The third layer can have a thickness of greater than 100 Å, greater than 500 Å, or greater than 500 Å.

Additional metal layers can be added in order to provide a gradient of thermal expansion coefficients thereby minimizing de-lamination during heat treatment. Adhesion has been shown to be improved when thermal expansion coefficients of selected materials were more closely matched.

Additional layers, such as a protective layer of material with a high chemical stability, or a capping layer can also be provided. Capping layers are described, for example, in U.S. Patent Publication 20050257824, which is incorporated by reference herein.

A system for generating electrical energy can include a transparent conductive layer, a semiconductor layer, a substrate supporting the semiconductor layer, and a first metal layer in contact with a semiconductor layer, a second metal layer including tungsten, molybdenum, iridium, tantalum, titanium, neodymium, palladium, lead, iron, silver, or nickel, the second layer in contact with the first metal layer, and a third metal layer.

A method of making a photovoltaic device substrate can include placing a semiconductor layer on a substrate, depositing a first metal layer in contact with a semiconductor layer, depositing a second metal layer including tungsten, molybdenum, iridium, tantalum, titanium, neodymium, palladium, lead, iron, silver, or nickel, the second layer in contact with the first metal layer, and depositing a third metal layer. The third layer can have a thickness of greater than 100 Å, greater than 500 Å, greater than 1000 Å, or greater than 2000 Å.

In certain circumstances, a first metal layer can be a chromium-containing layer, and a third metal layer can be an aluminum-containing layer. The second layer can be a nickel-containing layer. In another embodiment, a photovoltaic device can further comprise a fourth layer, wherein the fourth layer is an intermediate layer between the second metal layer and the third metal layer. The intermediate layer can be a nickel-containing layer. The intermediate layer can have a thickness of greater than 100 Å, greater than 500 Å, greater than 1000 Å, or greater than 2000 Å.

In yet another embodiment, a photovoltaic device can further comprise a fifth metal layer between the fourth metal layer and the third metal layer. The fifth layer can include lead, palladium, nickel, or silver. The fifth layer can have a thickness of greater than 100 Å, greater than 500 Å, greater than 1000 Å, or greater than 2000 Å.

In certain circumstances, a capping layer can be deposited in addition to a tin oxide protective layer. A capping layer can be positioned between the transparent conductive layer and the window layer. The capping layer can be positioned between the protective layer and the window layer. The capping layer can be positioned between the transparent conductive layer and the protective layer. The capping layer can serve as a buffer layer, which can allow a thinner window layer to be used. For example, when using a capping layer and a protective layer, the first semiconductor layer can be thinner than in the absence of the buffer layer. For example, the first semiconductor layer can have a thickness of greater than about 10 nm and less than about 600 nm. For example, the first semiconductor layer can have a thickness greater than 20 nm, greater than 50 nm, greater than 100 nm, or greater than 200 nm and less than 400 nm, less than 300 nm, less than 250 nm, or less than 150 nm.

The first semiconductor layer can serve as a window layer for the second semiconductor layer. By being thinner, the first semiconductor layer allows greater penetration of the shorter wavelengths of the incident light to the second semiconductor layer. The first semiconductor layer can be a group II-VI, III-V or IV semiconductor, such as, for example, ZnO, ZnS, ZnSe, ZnTe, CdO, CdS, CdSe, CdTe, MgO, MgS, MgSe, MgTe, HgO, HgS, HgSe, HgTe, AlN, AlP, AlAs, AlSb, GaN, GaP, GaAs, GaSb, InN, InP, InAs, InSb, TlN, TlP, TlAs, TlSb, or mixtures thereof. It can be a binary semiconductor, for example it can be CdS. The second semiconductor layer can be deposited onto the first semiconductor layer. The second semiconductor can serve as an absorber layer for the incident light when the first semiconductor layer is serving as a window layer. Similar to the first semiconductor layer, the second semiconductor layer can also be a group II-VI, III-V or IV semiconductor, such as, for example, ZnO, ZnS, ZnSe, ZnTe, CdO, CdS, CdSe, CdTe, MgO, MgS, MgSe, MgTe, HgO, HgS, HgSe, HgTe, AlN, AlP, AlAs, AlSb, GaN, GaP, GaAs, GaSb, InN, InP, InAs, InSb, TlN, TlP, TlAs, TlSb, or mixtures thereof. Deposition of semiconductor layers in the manufacture of photovoltaic devices is described, for example, in U.S. Pat. Nos. 5,248,349, 5,372,646, 5,470,397, 5,536,333, 5,945,163, 6,037,241, and 6,444,043, each of which is incorporated by reference in its entirety. The deposition can involve transport of vapor from a source to a substrate, or sublimation of a solid in a closed system. An apparatus for manufacturing photovoltaic devices can include a conveyor, for example a roll conveyor with rollers. Other types of conveyors are possible. The conveyor transports substrate into a series of one or more deposition stations for depositing layers of material on the exposed surface of the substrate. The deposition chamber can be heated to reach a processing temperature of not less than about 450° C. and not more than about 700° C., for example the temperature can range from 450-550, 550-650°, 570-600° C., 600-640° C. or any other range greater than 450° C. and less than about 700° C. The deposition chamber includes a deposition distributor connected to a deposition vapor supply. The distributor can be connected to multiple vapor supplies for deposition of various layers or the substrate can be moved through multiple and various deposition stations each station with its own vapor distributor and supply. The distributor can be in the form of a spray nozzle with varying nozzle geometries to facilitate uniform distribution of the vapor supply.

Devices including protective layers can be fabricated using soda lime float glass as a substrate. A film of ZnO:Al can be commercially deposited by sputtering or by atmospheric pressure chemical vapor deposition (APCVD). Other doped transparent conducting oxides, such as a tin oxide can also be deposited as a film. Conductivity and transparency of this layer suit it to serving as the front contact layer for the photovoltaic device.

A second layer of a transparent conducting oxide, such as tin oxide, or tin oxide with zinc can be deposited. This layer is transparent, but conductivity of this layer is significantly lower than an aluminum-doped ZnO layer or a fluorine doped SnO₂ layer, for example. This second layer can also serve as a buffer layer, since it can be used to prevent shunting between the transparent contact and other critical layers of the device. The protective layers were deposited in house by sputtering onto aluminum-doped ZnO layers during device fabrication for these experiments. The protective layers were deposited at room temperature. A silicon dioxide capping layer can be deposited over a transparent conducting oxide using electron-beam evaporation.

Devices can be finished with appropriate back contact methods known to create devices from CdTe PV materials. Testing for results of these devices was performed at initial efficiency, and after accelerated stress testing using I/V measurements on a solar simulator. Testing for impact of chemical breakdown in the front contact and protective layers was done with spectrophotometer reflectance measurements, conductivity (sheet resistance) measurements.

A number of embodiments have been described. Nevertheless, it will be understood that various modifications may be made without departing from the spirit and scope of the invention. For example, the semiconductor layers can include a variety of other materials, as can the materials used for the buffer layer and the protective layer. Accordingly, other embodiments are within the scope of the following claims.

What is claimed is:

1. A photovoltaic device comprising:
a transparent conductive layer;
a semiconductor layer, a substrate supporting the semiconductor layer; and
a first metal layer in contact with a semiconductor layer, and
a second metal layer including tungsten, molybdenum, iridium, tantalum, titanium, neodymium, palladium, lead, iron, silver, or nickel, the second layer in contact with the first metal layer.

2. The photovoltaic device of claim 1, further comprising a third metal layer over the second metal layer.

3. The photovoltaic device of claim 1, wherein the first metal layer is a chromium-containing layer.

4. The photovoltaic device of claim 2, wherein the third metal layer is an aluminum-containing layer.

5. The photovoltaic device of claim 1, the second layer having a thickness greater than 100 Å.

6. The photovoltaic device of claim 1, the second layer having a thickness greater than 500 Å.

7. The photovoltaic device of claim 1, the second layer having a thickness greater than 2000 Å.

8. The photovoltaic device of claim 1, the second layer having a thickness greater than 2000 Å.

9. The photovoltaic device of claim 2, further comprising a fourth layer, wherein the fourth layer is an intermediate layer between the second metal layer and the third metal layer.

10. The photovoltaic device of claim 9, wherein the intermediate layer is a nickel-containing layer.

11. The photovoltaic device of claim 9, the intermediate layer having a thickness greater than 100 Å.

12. The photovoltaic device of claim 9, the intermediate layer having a thickness greater than 500 Å.

13. The photovoltaic device of claim 9, the intermediate layer having a thickness greater than 1000 Å.

14. The photovoltaic device of claim 9, the intermediate layer having a thickness greater than 2000 Å.

15. The photovoltaic device of claim 1, further comprising a second semiconductor layer over the semiconductor layer.

16. The photovoltaic device of claim 9, further comprising a fifth metal layer between the fourth metal layer and the third metal layer.

17. The photovoltaic device of claim 16, wherein the fifth layer includes lead, palladium, nickel, or silver.

18. A system for generating electrical energy comprising:
a transparent conductive layer;
a semiconductor layer, a substrate supporting the semiconductor layer; and
a first metal layer in contact with a semiconductor layer,
a second metal layer including tungsten, molybdenum, iridium, tantalum, titanium, neodymium, palladium, lead, iron, silver, or nickel, the second layer in contact with the first metal layer, and
a third metal layer over the second layer;
a first electrical connection connected to the transparent conductive layer; and
a second electrical connection connected to the third metal layer.

19. The system of claim 18, wherein the first metal layer is a chromium-containing layer.

20. The system of claim 18, wherein the third metal layer is an aluminum-containing layer.

21. The system of claim 18, the second layer having a thickness greater than 100 Å.

22. The system of claim 18, the second layer having a thickness greater than 500 Å.

23. The system of claim 18, the second layer having a thickness greater than 1000 Å.

24. The system of claim 18, the second layer having a thickness greater than 2000 Å.

25. The system of claim 18, further comprising a fourth layer, wherein the fourth layer is intermediate layer between the second metal layer and the third metal layer.

26. The system of claim 25, wherein the intermediate layer is a nickel-containing layer.

27. The system of claim 25, the intermediate layer having a thickness greater than 100 Å.

28. The system of claim 25, the intermediate layer having a thickness greater than 500 Å.

29. The system of claim 25, the intermediate layer having a thickness greater than 1000 Å.

30. The system of claim 25, the intermediate layer having a thickness greater than 2000 Å.

31. The system of claim 18, further comprising a second semiconductor layer over the semiconductor layer.

32. The system of claim 25, further comprising a fifth metal layer between the fourth metal layer and the third metal layer.

33. The system of claim 32, wherein the fifth layer includes lead, palladium, nickel, or silver.

34. A method of manufacturing a photovoltaic device comprising:
placing a semiconductor layer on a substrate;
depositing a first metal layer in contact with a semiconductor layer, depositing a second metal layer including tungsten, molybdenum, iridium, tantalum, titanium, neodymium, palladium, lead, iron, silver, or nickel, the second layer in contact with the first metal layer, and
depositing a third metal layer over the second metal layer.

35. The method of claim 34, wherein the first metal layer is a chromium-containing layer.

36. The method of claim 34, wherein the third metal layer is an aluminum-containing layer.

37. The method of claim 34, the second layer having a thickness greater than 100 Å.

38. The method of claim 34, the second layer having a thickness greater than 500 Å.

39. The method of claim 34, the second layer having a thickness greater than 1000 Å.

40. The method of claim 34, the second layer having a thickness greater than 2000 Å.

41. The method of claim 34, further comprising a fourth layer, wherein the fourth layer is intermediate layer between the second metal layer and the third metal layer.

42. The method of claim 41, wherein the intermediate layer is a nickel-containing layer.

43. The method of claim 41, the intermediate layer having a thickness greater than 100 Å.

44. The method of claim 41, the intermediate layer having a thickness greater than 500 Å.

45. The method of claim 41, the intermediate layer having a thickness greater than 1000 Å.

46. The method of claim 41, the intermediate layer having a thickness greater than 2000 Å.

47. The method of claim 41 further comprising a second semiconductor layer over the semiconductor layer.

48. A photovoltaic device comprising:
a transparent conductive layer;
a semiconductor layer, a substrate supporting the semiconductor layer; and
a metal layer in contact with a semiconductor layer, wherein the metal layer is a nickel-containing layer.

49. The photovoltaic device of claim 48, further comprising a second metal layer over the nickel-containing layer.

50. The photovoltaic device of claim 49, wherein the second metal layer is an aluminum-containing layer.

51. The photovoltaic device of claim 49, further comprising a third metal layer over the second metal layer, the second metal layer have a thermal expansion coefficient greater than a thermal expansion coefficient of the first layer and less than a thermal expansion coefficient of the third layer.
